(19) United States
(12) Patent Application Publication
(10) Pub. No.: US 2024/0097601 A1
(43) Pub. Date: Mar. 21, 2024

(54) Tandem Photovoltaic Cell Structure

(71) Applicant: THE REGENTS OF THE UNIVERSITY OF MICHIGAN, Ann Arbor, MI (US)

(72) Inventors: Stephen R. FORREST, Ann Arbor, MI (US); Tobias BURGER, Ann Arbor, MI (US); Andrej LENERT, Ann Arbor, MI (US); Bosun ROY-LAYINDE, Ann Arbor, MI (US); Jinun LIM, Ann Arbor, MI (US)

(73) Assignee: THE REGENTS OF THE UNIVERSITY OF MICHIGAN, Ann Arbor, MI (US)

(21) Appl. No.: 18/369,956

(22) Filed: Sep. 19, 2023

Related U.S. Application Data
(60) Provisional application No. 63/407,876, filed on Sep. 19, 2022.

(51) Int. Cl. H02S 10/30; H01L 31/0725; H01L 31/0735; H01L 31/18

(52) U.S. Cl. CPC H02S 10/30; H01L 31/0725; H01L 31/0735; H01L 31/1844

(57) ABSTRACT

A tandem photovoltaic (PV) may include III-V semiconductors, silicon, a cathode electrode, an anode electrode, and a gold-to-gold metal bridge electrode. The semiconductors include p-typed and n-typed regions. To form a tandem PV structure, bottom and top PV cells can be independently fabricated. The bottom and the top PV cells are electrically connected by the gold-to-gold metal bridge interconnection, which is positioned between the bottom and the top PV cells. The metal bridge may be formed by cold-welding compression technique. This structure is compatible to the development of tandem PVs as well as thermophotovoltaic (TPV) cells.

### CROSS-REFERENCE TO RELATED APPLICATIONS

This application claims the benefit of U.S. Provisional Application No. 63/407,876, filed on Sep. 19, 2022. The entire disclosure of the above application is incorporated herein by reference.

### GOVERNMENT CLAUSE

This invention was made with government support under 2018572 awarded by the National Science Foundation. The government has certain rights in the invention.

### FIELD

The present disclosure relates to tandem photovoltaic devices and fabrication methods thereof.

### BACKGROUND

Tandem photovoltaic (PV) devices have top and bottom cells comprised of different materials and bandgaps (e.g., III-V semiconductors and silicon). A heavily doped tunnel junction layer is inserted between the two cells and electrically connects them. However, there are a few challenges to developing the tandem photovoltaic devices. One is heteroepitaxial thin film growth and the second is to form a tunnel junction region with heavily doped p-type and n-type layers. Semiconductors mostly have different lattice constants, which limit lattice-matched epitaxial growth on a substrate. A few material combinations can be epitaxially grown on a substrate. For instance, GaAs (E_{g}=1.42 eV) is lattice-matched to In_{0.5}Ga_{0.5}P (E_{g}=2.12 eV) and In_{0.53}Ga_{0.47}As (E_{g}=0.74 eV) can be epitaxially grown on InP (E_{g}=1.34 eV). Most of the materials are not lattice-matched to each other including silicon.

Therefore, it is desirable to develop a method to fabricate optoelectronic devices with a tandem photovoltaic (PV) cell structure but without the requirement of heavy-doped tunnel junctions and lattice-matched material interfaces between top and bottom cells.

This section provides background information related to the present disclosure which is not necessarily prior art.

### SUMMARY

This section provides a general summary of the disclosure, and is not a comprehensive disclosure of its full scope or all of its features.

An optoelectronic device is presented. The optoelectronic device includes: a substrate; a bottom electrode disposed on the substrate; a bottom photovoltaic cell disposed on the bottom electrode; a bottom bridge layer disposed on the bottom photovoltaic cell; a top bridge layer disposed on the bottom bridge layer and bonded thereto; a top photovoltaic cell disposed on the top bridge layer, such that the top bridge layer and the bottom bridge layer form a shared electrode between the top photovoltaic cell and the bottom photovoltaic cell; and a top electrode disposed on the top photovoltaic cell. The top and bottom bridge layer may be comprises of metal and include a hole through which thermal radiation passes.

In one aspect, the top bridge layer is bonded to the bottom bridge layer using cold weld bonding.

Each of the top and bottom photovoltaic cells are comprised of multiple device layers forming a p-n junction. In one embodiment, the multiple device layers of at least one of the top photovoltaic cell and the bottom photovoltaic cell include a layer of indium gallium arsenide sandwiched between layers of indium phosphide. In other embodiments, the multiple device layers of the top photovoltaic cell and the bottom photovoltaic cell are comprised of other types of semiconductors selected from group III-V elements.

In some embodiments, a terminal electrically is coupled to the shared electrode formed by the top bridge layer and the bottom bridge layer. In yet other embodiments, a third photovoltaic cell is interposed between the top photovoltaic cell and the top electrode.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an exploded view of an example embodiment of optoelectronic device having a tandem photovoltaic cell structure.

FIGS. 2A and 2B illustrate lattice structures of a top bridge layer and a bottom bridge layer parallelly aligned.

FIGS. 2C and 2D illustrate lattice structures of a top bridge layer and a bottom bridge layer cross aligned.

FIGS. 3A-3C are schematics of an optoelectronic device with a tandem cell structure and different terminal arrangements.

FIG. 4 is a graph showing simulated current-voltage (J-V) curves for an optoelectronic device having single PV cell structure and a tandem PV cell structure.

FIG. 5 is a diagram of an optoelectronic device having three photovoltaic cells.

FIGS. 6A-6C are schematics for tandem photovoltaic cell structures having two terminal, three terminal and four terminal arrangements, respectively.

FIGS. 7A-7F illustrate an example fabrication process for a tandem photovoltaic cell having two air bridges.

FIGS. 8A-8F illustrate an example fabrication process for a tandem photovoltaic cell having one air bridge.

FIGS. 9A-9D depict an example embodiment of a tandem photovoltaic cell structure having two terminal arrangement.

FIG. 10A-10D are graphs showing measured and simulated test results for the tandem photovoltaic cell structure having two terminal arrangement.

FIG. 11A depicts an example embodiment of a tandem photovoltaic cell structure having three terminal arrangement.

FIGS. 11B and 11C are graphs showing measured and simulated test results for the tandem photovoltaic cell structure having three terminal arrangement.

FIGS. 12A and 12B are graphs showing current-voltage and power-voltage characteristics, respectively, for the tandem photovoltaic cell structure having three terminal arrangement.

FIGS. 12C and 12D are graphs comparing performance of the tandem photovoltaic cell structure with a two terminal arrangement to one with a three terminal arrangement.

FIG. 13A depicts an example embodiment of a tandem photovoltaic cell structure having four terminal arrangement.

FIG. 13B is a graph showing the calculated spectral absorption in the cells of the tandem photovoltaic cell structure having four terminal arrangement.

FIGS. 14A-14C are graphs showing measured test results for the tandem photovoltaic cell structure having four terminal arrangement.

FIG. 15 is a diagram depicting interconnects for the tandem photovoltaic cell structure having four terminal arrangement.

FIG. 16A-16D illustrate an alternative grid line arrangement for use in a tandem photovoltaic cell structure.

Corresponding reference numerals indicate corresponding parts throughout the several views of the drawings.

### DETAILED DESCRIPTION

Example embodiments will now be described more fully with reference to the accompanying drawings.

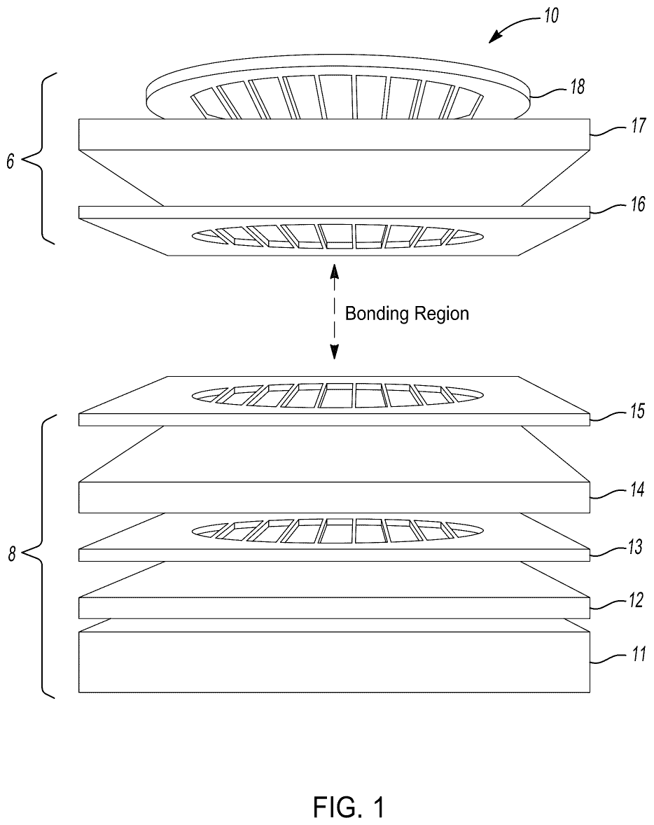

FIG. 1 depicts an example embodiment of an optoelectronic device 10 having a tandem photovoltaic (PV) cell structure. Exemplary embodiments provide a non-conventional but promising method to facilitate tandem photovoltaic device fabrications without the requirement of heavy-doped tunnel junctions and the lattice-matched material interface between bottom and top cells. This disclosure proposes to fabricate tandem PV cells with a few microns of semiconductor thin films with mechanical stability. To be specific, this disclosure enables to fabricate high efficient tandem thermophotovoltaics with 3D stack of air-bridges. While reference is made throughout this disclosure to photovoltaic cells, the techniques described herein are applicable to thermophotovoltaic cells as well.

In one embodiment, the optoelectronic device 10 includes a substrate 11 with a top photovoltaic cell 6 and a bottom photovoltaic cell 8 supported thereon. For the bottom photovoltaic cell 8, a bottom electrode 12 is disposed on the substrate 11; one or more device layers 14 are disposed on the bottom electrode 12; a bottom bridge layer 15 is disposed on the device layers 14. The bottom bridge layer 15 is comprised of metal (e.g., gold) and includes a hole through which thermal radiation passes. Next, a top bridge layer 16 is disposed on the bottom bridge layer 15 and bonded thereto. Similarly, the top bridge layer 16 is comprised of metal and includes a hole through which thermal radiation passes. One of more device layers 17 for the top photovoltaic cell is then disposed on the top bridge layer 16, such that the top bridge layer 16 and the bottom bridge layer 15 form a shared electrode between the top photovoltaic cell 6 and the bottom photovoltaic cell 8. Lastly, a top electrode 18 is disposed on the device layers 17 of the top photovoltaic cell. In the example embodiment, the top bridge layer 16 and the bottom bridge layer 15 are bonded together, for example using cold weld bonding.

Each of the top photovoltaic cell 6 and the bottom photovoltaic cell 8 is comprised of multiple device layers forming a p-n junction. In one example, the multiple device layers of the top photovoltaic cell and the bottom photovoltaic cell include a layer of indium gallium arsenide sandwiched between layers of indium phosphide. Other semiconductor materials are contemplated by this disclosure, including semiconductors selected from group III-V elements.

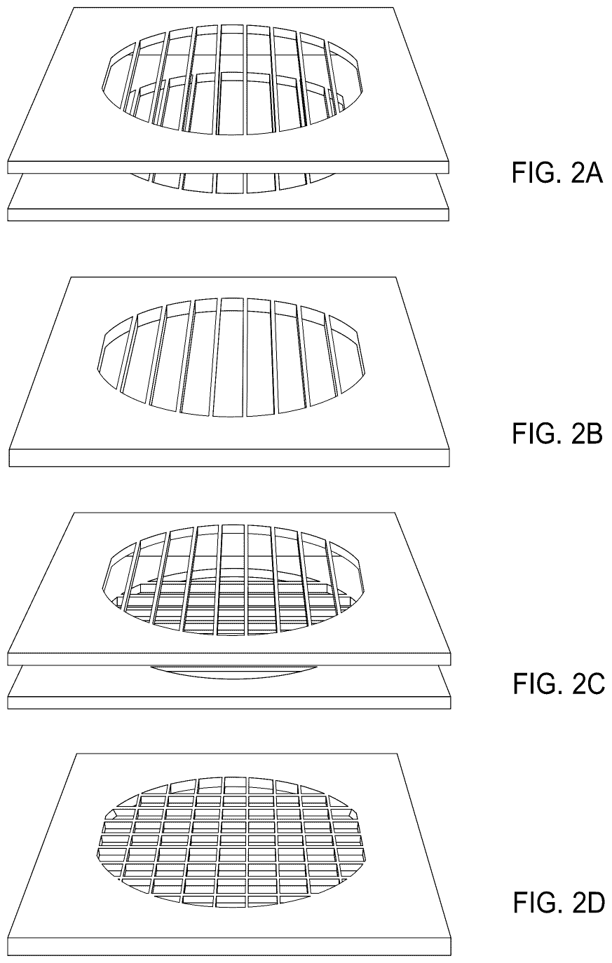

In an example embodiment, the top bridge layer 16 and the bottom bridge layer 15 include holes which align with each other. In other embodiments, the holes in the top bridge layer 16 and the bottom bridge layer 15 have a lattice structure formed therein. The lattice structures of the top bridge layer 16 and the bottom bridge layer 15 may be parallelly aligned as seen in FIGS. 2A and 2B. Alternatively, the lattice structures of the top bridge layer 16 and the bottom bridge layer 15 may be cross-aligned as seen in FIGS. 2C and 2D. Other structures that allow light (or thermal radiation) to pass through are envisioned for the top and bottom bridge layers.

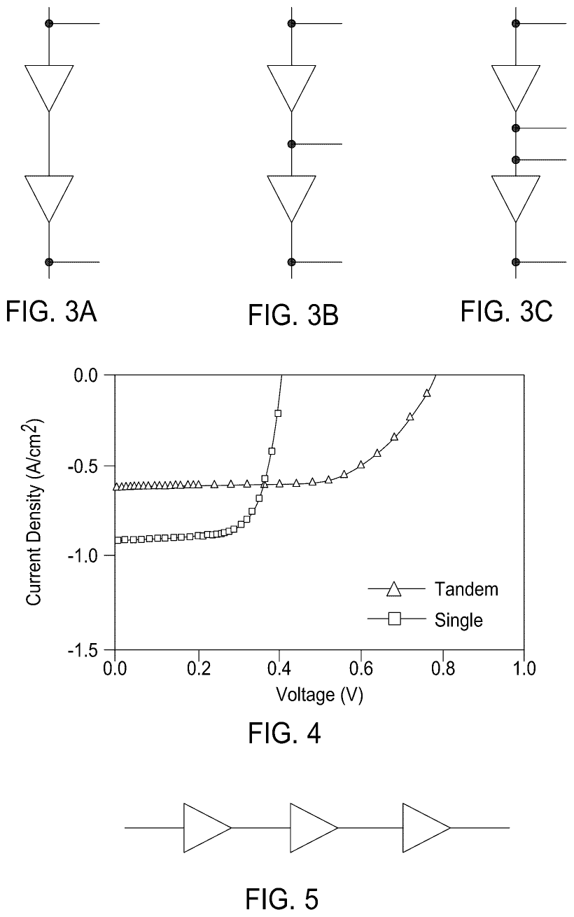

An optoelectronic device 10 having a tandem photovoltaic (PV) cell structure may be configured with different terminal arrangements as seen in FIGS. 3A-3C. With reference to FIG. 3A, the optoelectronic device 10 may have two terminals, for example as seen in FIG. 1.

In FIG. 3B, the optoelectronic device 10 is configured with three terminals. That is, a third terminal 33 is electrically coupled to the shared electrode formed by the top bridge layer and the bottom bridge layer. In this way, each photovoltaic cell can output current separately.

In FIG. 3C, the optoelectronic device 10 is configured with four terminals. More specifically, a top terminal 34 is electrically coupled to the top bridge layer 16, such that the top photovoltaic cell is able to output current therefrom, and a bottom terminal 35 is electrically coupled to the bottom bridge layer 15. In this case, an insulator layer is disposed between the top bridge payer 16 and the bottom bridge layer 15.

FIG. 4 is a graph comparing simulated current-voltage (J-V) curves under the light-spectrum of 1300K for an optoelectronic device having single PV cell structure and a tandem PV cell structure. For this demonstration, the photovoltaic cells are comprised of semiconductors selected from group III-V elements (i.e., In—Ga—As and In P). As shown in Table 1, the max power can be increased by 20% or more.

TABLE 1
Simulated electrical parameters comparison
between the single and the tandem TPVs.

| | Short-circuit | Open-circuit | Fill- | Max |
|---|---|---|---|---|
| | current | voltage | factor | power |
| Device | (A/cm²) | (V) | (%) | (W/cm²) |
| Single | 0.91 | 0.41 | 69 | 0.26 |
| Tandem | 0.61 | 0.78 | 64 | 0.31 |

FIG. 5 further illustrates an embodiment of the optoelectronic device having three photovoltaic cells. Although three photovoltaic cells are shown in this embodiment, an optoelectronic device having more three photovoltaic cells is also contemplated by this disclosure. It is envisioned that the photovoltaic cells can be grown on separate wafers and then combined to form the optoelectronic device.

Conventional multi-junction cells rely on tunnel junctions, which are heavily doped layers that connect the top and bottom cells in series. Tunnel junctions work well for direct solar conversion, where photon recuperation is unimportant. However, tunnel junctions are problematic for thermal batteries because most of the incident power is out-of-band and the spectrum changes significantly during the battery discharge phase (i.e., as the media cool from 2200 to 1600° C.). Specifically, tunnel junctions (1) introduce unacceptably large parasitic absorption below the bandgap due to free carriers and ionized donors/acceptors, and (2) constrain the current produced by the top and bottom cell to be equal, which results in large power losses as the spectrum changes. The combination of these factors limits both the peak and average efficiencies during the discharge phase. The high current densities at which TPVs operate also pose a challenge for minimizing voltage loss from a tunnel junction. To overcome existing limitations in multi-junction TPV cells, this disclosure makes use an intermediate metallic grid in place of a tunnel junction to mechanically support and electrically connect the sub cells together.

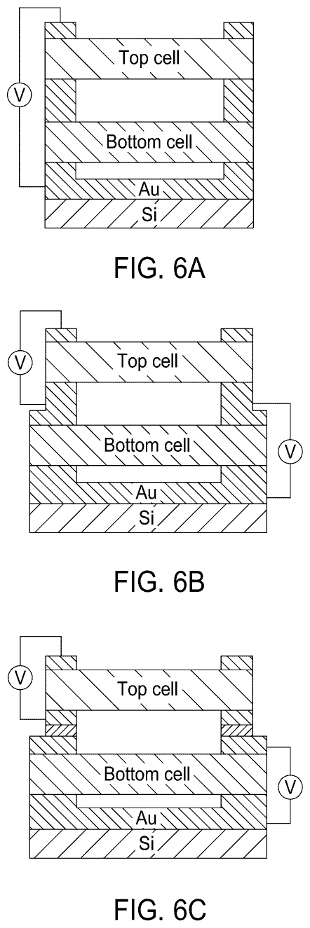

With reference to FIGS. 6A-6C, overall structure for an optoelectronic device not only merges the advantages of multi-junction cells with the novel air-bridge architecture, but it adds another layer of innovation by allowing straightforward access to the middle electrodes which enables fabrication of multi terminals. This would not be possible using state-of-the-art tunnel junctions. This approach features several notable advances in optoelectronic devices with tandem PV cell structures.

First, the proposed tandem reflects nearly all the radiation that is not absorbed by the top and bottom cells (Rₒᵤₜ ˜99%). Replacing conventional tunnel junctions with thermo-compression metal bonds minimizes parasitic absorption of incident radiation by (1) using metal grids with high IR reflectance (˜99%) to conduct current, (2) situating all the relatively high-doped regions (i.e., contact regions) underneath the metal grids where they are shaded, and (3) introducing air gaps between absorbers that are free of parasitic absorption and maximize the refractive index-mismatch at each interface. The outcome is a design that circumvents an expected 3-6% loss in Rₒᵤₜ by eliminating the tunnel junction and increasing the peak efficiency by 10-15% absolute. Higher TPV efficiency translates to higher thermal battery round trip efficiency (RTE) and therefore more opportunities to generate revenue from arbitrage. This can be understood by considering a scenario in which electricity is available at $0.02/kWh-e during times of low demand and can be sold at $0.05/kWh-e during times of high demand (e.g., 24-48 h later). Furthermore, the temperature insensitivity resulting from high Rₒᵤₜ allows operators to stretch the difference between the highest and lowest operating temperature of the storage medium, which increases the resulting storage capacity and improves grid resilience.

Second, the multi-terminal configuration eliminates the current-matching constraint which further decreases the sensitivity to changes in the temperature of the energy storage medium over a very wide range. For example, the proposed 4T tandems would allow operators to regularly discharge stored energy from 2200° C. down to 1600° C. while maintaining 50°/o average RTE. In contrast, current-matched 2T devices are limited to less than half this range. Doubling the Thot range doubles the amount of energy stored per unit mass and can reduce by half the cost per unit energy (CPE) of the battery. Furthermore, the design gives grid operators more flexibility and a faster return on the investment by allowing them to further stretch the temperature difference to 1500-2300° C. during outages or periods of sustained demand, while incurring only minor efficiency losses.

Third, sequential cell cold-weld bonding loosens epitaxial lattice matching constraints by pairing dissimilar materials that are grown on different substrates (e.g., GaAs, Si, InP) and then transferred to the tandem stack. This provides significant flexibility in cell design and performance.

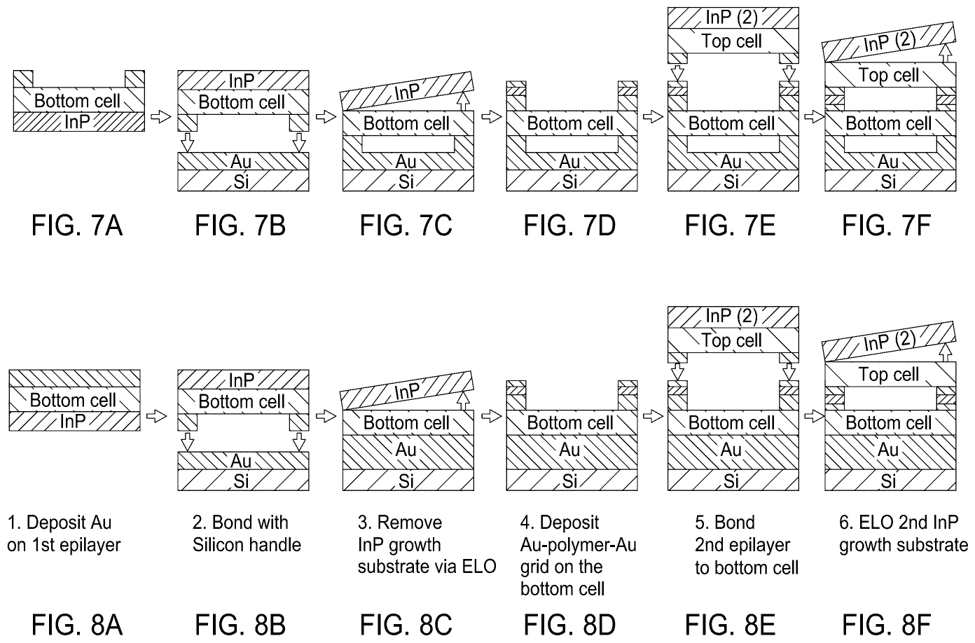

Referring to FIGS. 7A-7F and 8A-8F, fabrication of the airbridge tandem device is achieved through modification of the cold weld bonding procedure developed for single-junction air-bridge cells. In FIGS. 7A-7F, the bottom cell is a single junction air-bridge cell, forming a dual air-bridge tandem; whereas, in FIGS. 8A-8F, the bottom cell is a conventional gold mirror without the air-bridge, forming a tandem with a single airbridge. This method can be extended to form tandems with more than two sub cells by continuously bonding the different sub cells on one another.

The key enabling technique of the proposed approach is the air-bridge technology. The approach allows arbitrary pairing of epitaxial semiconductor devices and substrates using a precise cold-weld transfer method, thus forming the desired tandem architecture. The transfer relies on the deposition and patterning of a metal grid (e.g., gold) on the epitaxially grown layer (epilayer). This step is followed by thermocompression bonding (10 MPa, 150° C.) of the grid to a (gold coated) substrate that causes a seamless bond. The simplicity of this process makes it suitable for scale-up and commercialization. Moreover, the metal-metal bond minimizes thermal resistance between the active layers and the carrier handle, unlike approaches that use epoxy-based bonding.

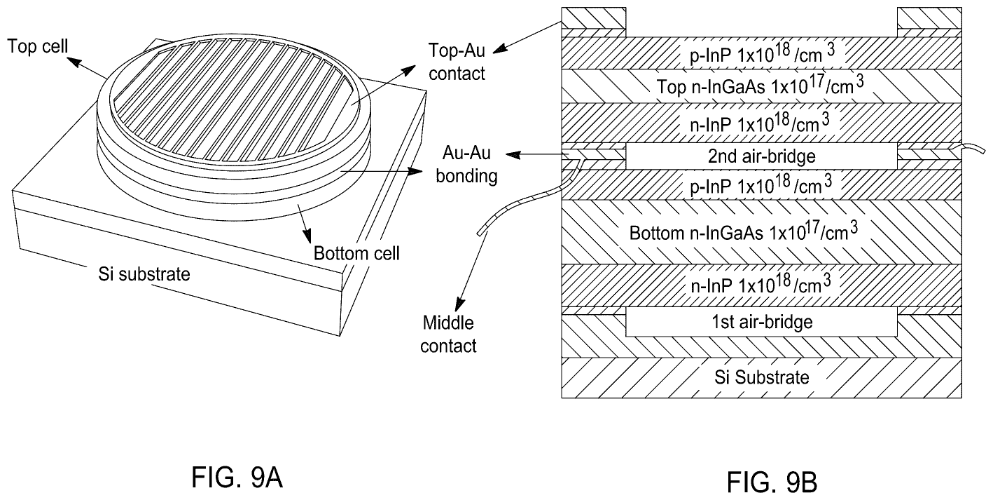

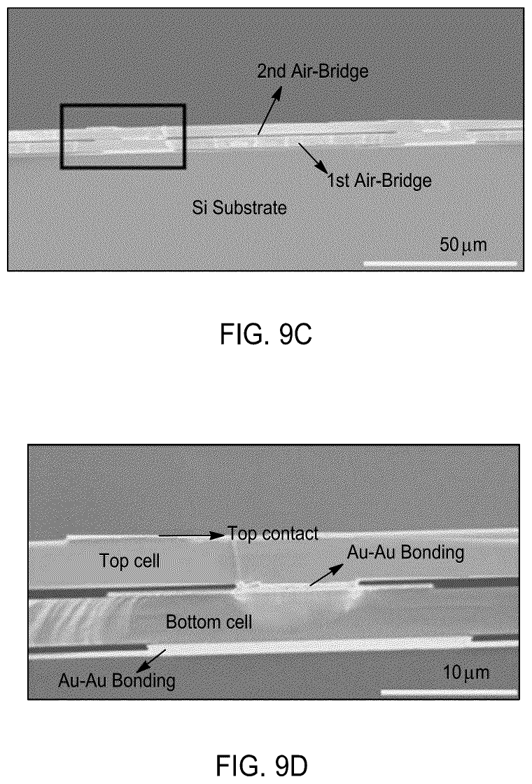

Different multi-terminal arrangements are further discussed below. For a two terminal tandem cell arrangement, a “homotandem” configuration is used as seen in FIG. 9A-9D, where the top and bottom cells are made of the same 0.74-eV InGaAs absorbers lattice matched to the InP growth substrate. The first epilayer, which will become the bottom absorber, is bonded to the host Si substrate by Au—Au thermocompression bonding (10 MPa, 150° C.). Upon bonding, the InP growth substrate is removed using epitaxial lift-off (ELO).

An intermediate grid that covers ˜20% of the area is used to mechanically support the second epilayer and electrically isolate the two sub cells. The intermediate grid is realized by deposition of complimentary grid lines on the bottom cell and the epilayer used for the top cell. After removal of the second InP substrate (from top cell) using ELO, device areas are defined using standard III-V wet etching procedures through the use of outer rings. Lastly, the third and final set of Au grid lines are deposited to provide a top electrical contact. Spatial alignment of the top grid to the intermediate grid is performed to provide mechanical support for the top grid and to minimize shading of the bottom cell.

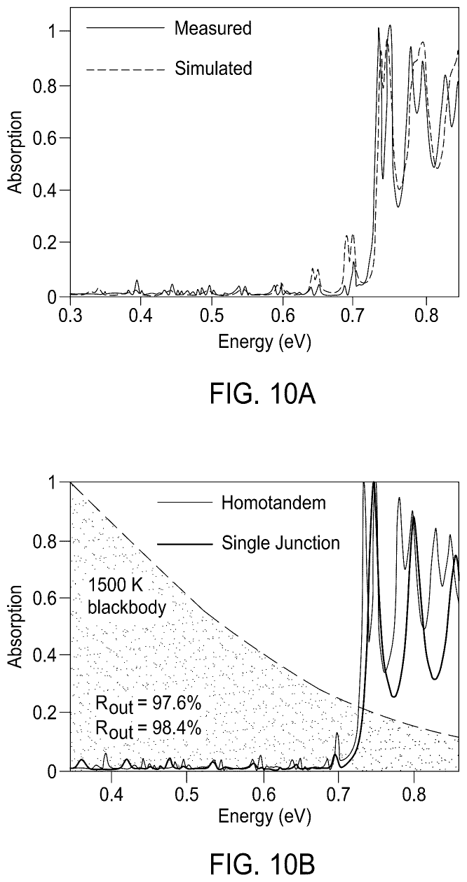

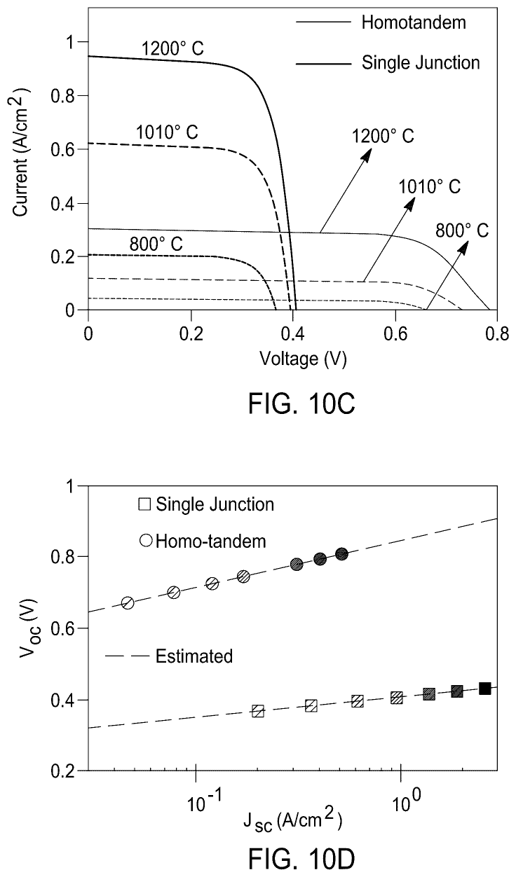

To check the optical property of the structure, Fourier transform infrared spectroscopy (FTIR) measurements were taken on the tandem cell and compared to simulation results. The simulation was done using transfer matrix method with properties specific to our InGaAs material as input. The measured absorption spectrum is similar to the simulated results as shown in FIG. 10A. The experimental tandem cell was also compared to a single junction and the out-of-band reflectance is within a 1% absolute difference as shown in FIG. 10B. This indicates one can fabricate a tandem structure while still maintaining the highly reflecting properties of a single junction. Current-voltage measurements were taken for both the single junction and tandem cell at different temperatures (FIG. 10C). This highlights the tandem cell is operating at a lower photocurrent relative to a single junction. Such phenomenon can be attributed to the bottom cell which is current limiting because most of the above-bandgap photons will be absorbed in the top cell. This is disadvantageous because the tandem cell will have to operate at this low current thereby reducing the power produced. In FIG. 10D, the open circuit voltages (V_{oc}) as a function of photocurrent densities (Jₚₕ) is compared for both the single junction and tandem and one sees that the V_{oc} of tandem is approximately twice the single junction as expected.

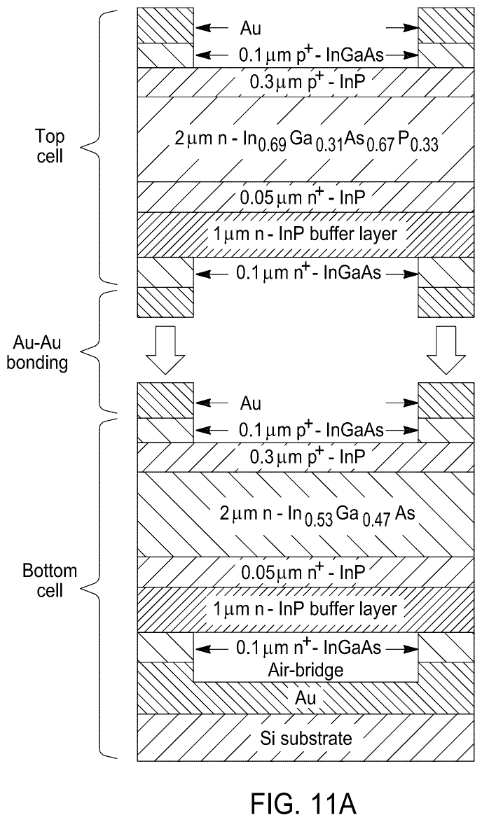

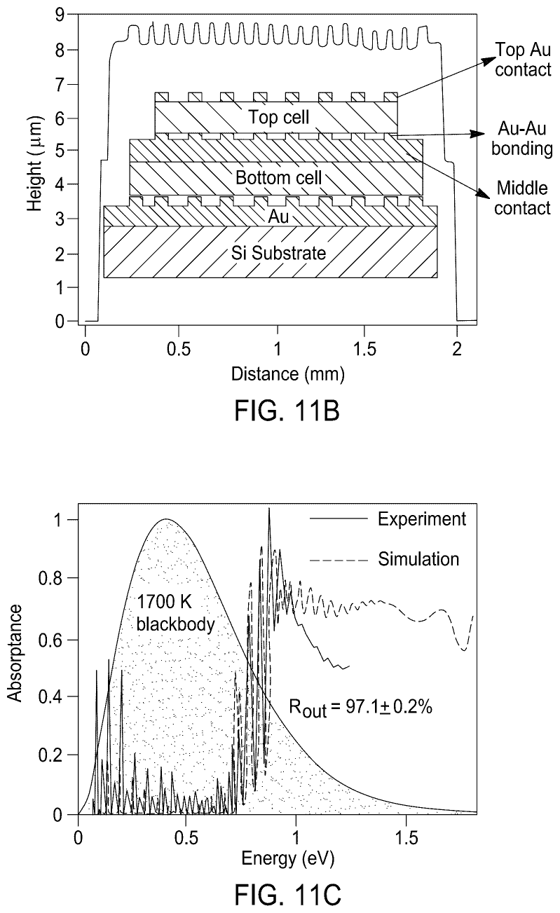

To overcome the current matching constraint in a two terminal configuration, one can operate the top and bottom cells as a three terminal device or a four terminal device. To demonstrate the three terminal concept, the top and bottom cells use different bandgaps (a 0.9 eV InGaAsP top cell and a 0.74 eV InGaAs bottom cell) as shown in FIG. 11A. With similar fabrication steps as shown in FIG. 8, top and bottom cells made of different bandgap materials are bonded, with an additional fabrication step of revealing and patterning the intermediate metal as a middle electrode. To check the mechanical stability of the airgap suspension, profilometry measurements were taken by scanning the surface as shown in FIG. 11B.

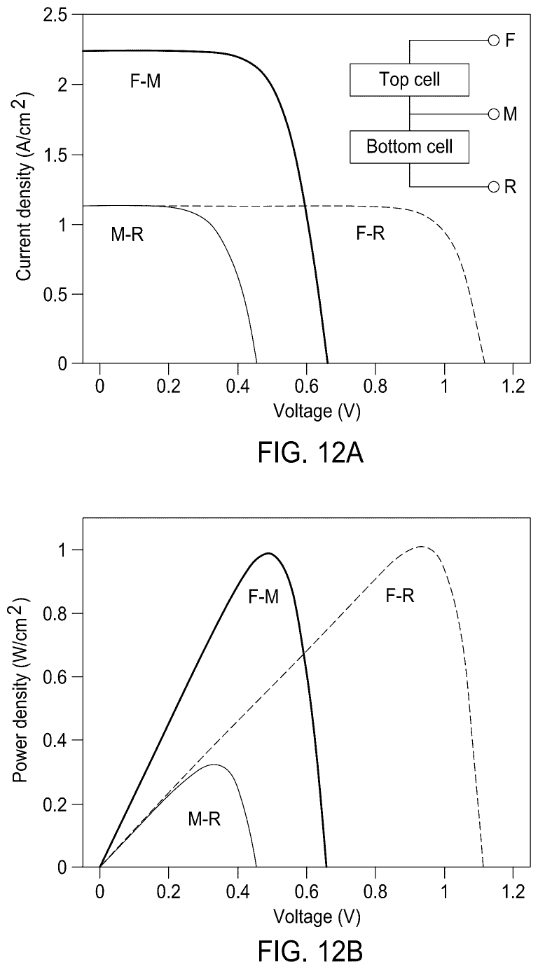

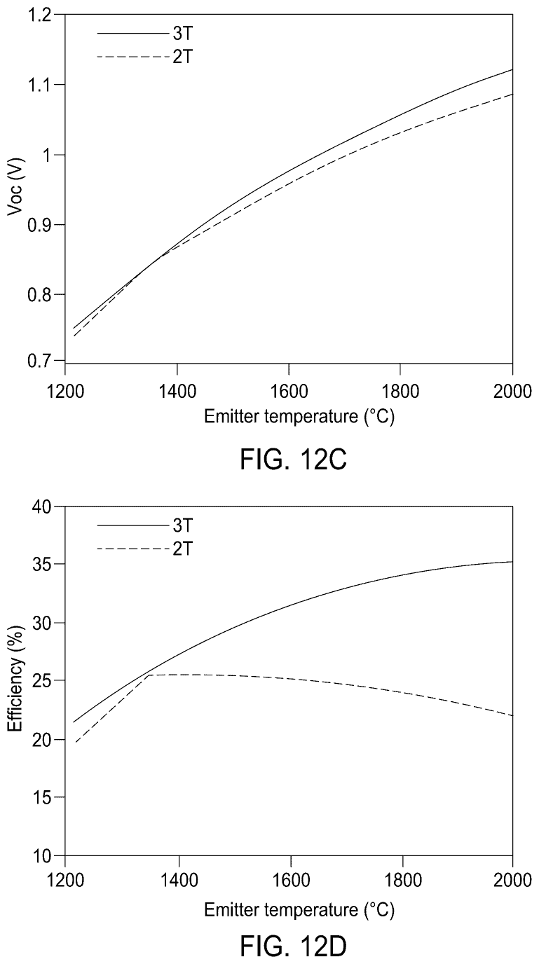

To test the optical property of the structure, Fourier transform infrared spectroscopy (FTIR) measurements were taken on the tandem cell and compared to simulation results as shown in FIG. 11C. The tandem has a Rₒᵤₜ of 97%, with the 3% loss in reflectance majorly attributed to parasitic absorption in the absorber layers of the top and bottom cell. Modeling was also used to describe the electrical performance of this tandem when operated in 3T mode, in which the front (F) and rear (R) electrodes can be directly operated as a traditional 2T. When used in a 2T configuration, the model demonstrates that the bottom cell, i.e. middle (M) to rear operation, is current limiting as shown in FIG. 12B, and thus power that would have been lost in a 2T operation is collected using the F-M electrodes of a 3T cell. It was also shown that if the 3T cell is operated as 2T (assuming the cells are connected in series), the open circuit voltage (V_{oc}) of the 3T arrangement is higher than the 2T arrangement at higher temperatures as shown in FIG. 12C. This is because the 2T cell would be operating at a lower current due to the current matching restraint and thus producing a lower open circuit voltage. Finally, the 3T arrangement helps mitigate the effects of spectral variation by maintaining a wider range of high efficiencies relative to the 2T configuration as shown in FIG. 12D.

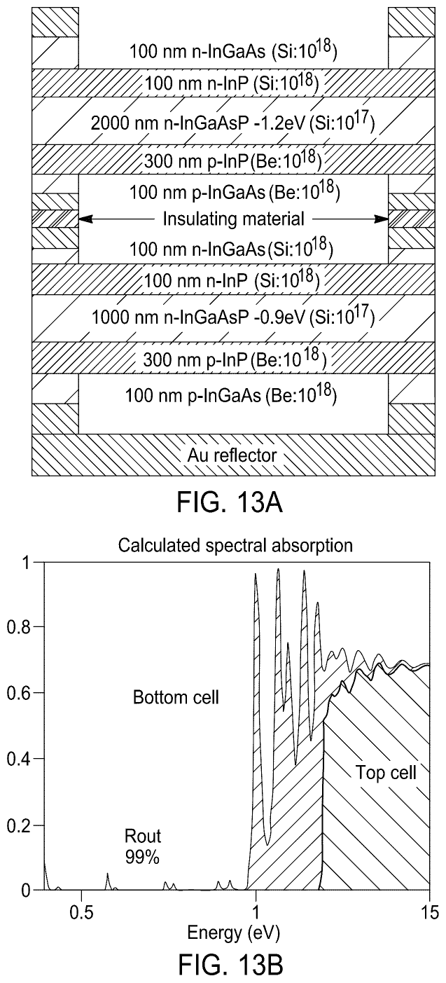

To demonstrate 4T capacity, a tandem featuring a ˜1.2 eV top cell and the ˜0.9 eV bottom cell as shown in FIG. 13A. Using wider bandgaps will improve output power and conversion efficiency at the high temperatures encountered in thermal battery applications. The bottom cell is compression bonded to a metal-coated substrate using a patterned rear electrode, resulting in air gaps between metal gridlines. The top cell is then connected to the bottom cell using a patterned metal-insulator-metal grid. The thin insulating layer between the top and bottom cells serves to electrically isolate the cells, allowing them to be integrated into a module configuration without introducing thermal resistance.

In this configuration, the choice of insulating material is very important as it needs to eliminate any current leakage between the sub cells. Materials such as parylene and polyimide can be used as insulating material in this 4T configuration as shown in optical microscopy images during the fabrication process. The fabrication method is similar to that in FIG. 7 but includes the 1-2 μm thick polyimide layer (or any other insulating material) as an insulator between the sub-cells. The polyimide (PI-2555, HD Microsystems) is spin-coated on the bottom cell and patterned by dry-etching process using oxygen plasma (the O2 flow of 20 ppm with a plasma power 150 W). Another thin gold layer is patterned on the polyimide, and the top and bottom cells are joined by the Au—Au cold welding method. The thick polyimide guarantees insulation between the sub-cells. However, the adhesion between polyimide and metals becomes poor owing to humidity penetration and HCl chemical attack on the Ti layers between gold and polyimide. Therefore, good adhesion is important to prevent a peel-off of the top cell and a substantial electrical leakage path through the sub-cells. This can be achieved by using a metal adhesion layer or coating the edges of the cell with photoresist after bonding.

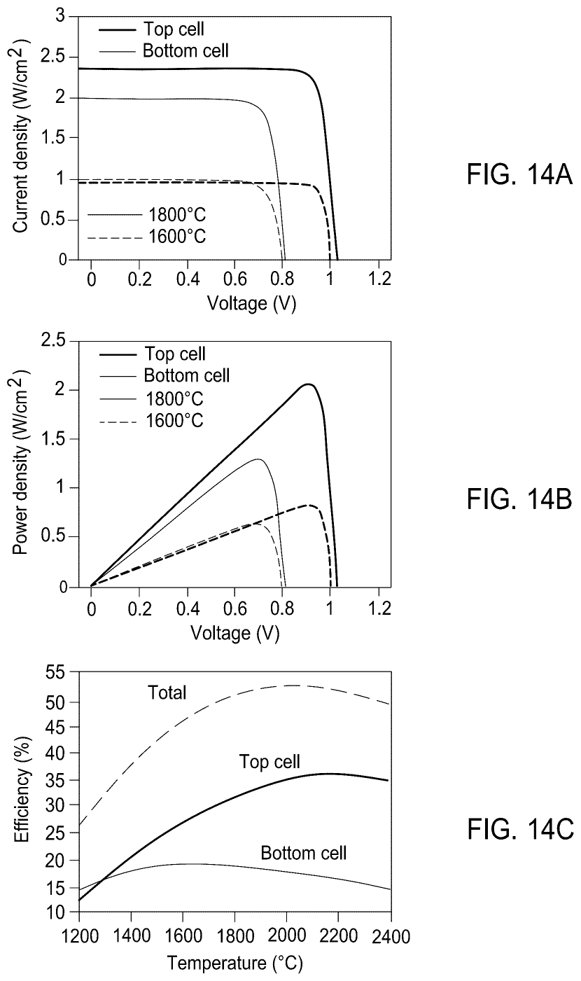

When operated in the 4T configuration, the current-voltage and power-voltage characteristics at two representative temperatures (1600° C. and 1800° C.) are shown in FIGS. 14A and 14B, respectively. Both the modeled electronic and optical performance are used to predict the efficiency of the 4T configuration. Since both sub-cells are operating independently, the efficiency of the 4T configuration is the sum of the efficiencies of the top and bottom cells as shown in FIG. 14C. The model predicts efficiencies greater than 50% when operating in 4T configuration. Beyond reaching >50% efficiency at the cell level, the integration of multi-junction cells into modules also presents challenges related to minimizing series resistance (Ohmic) losses, managing cell temperature, and maximizing the active area to allow for nearly lossless photon recuperation. Addressing these challenges would unlock the full potential of thermal batteries as an energy system that provides ultra-low-cost approach to storing electricity for days.

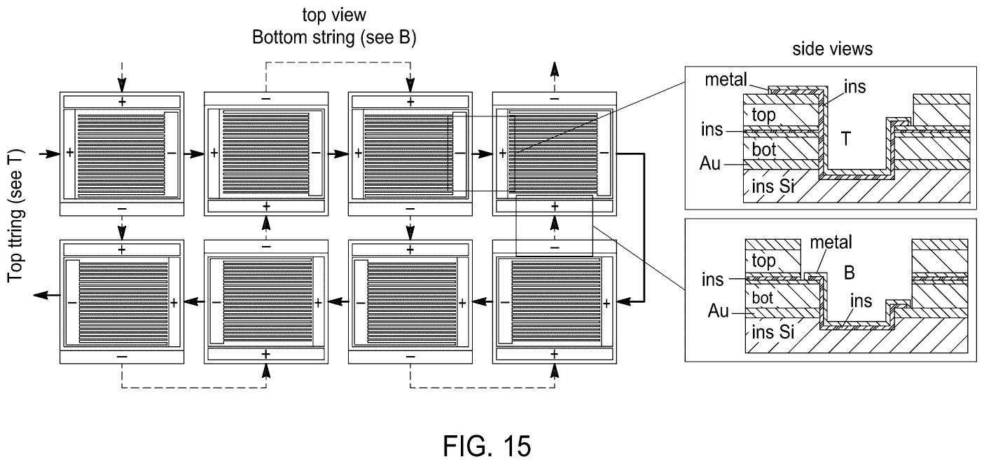

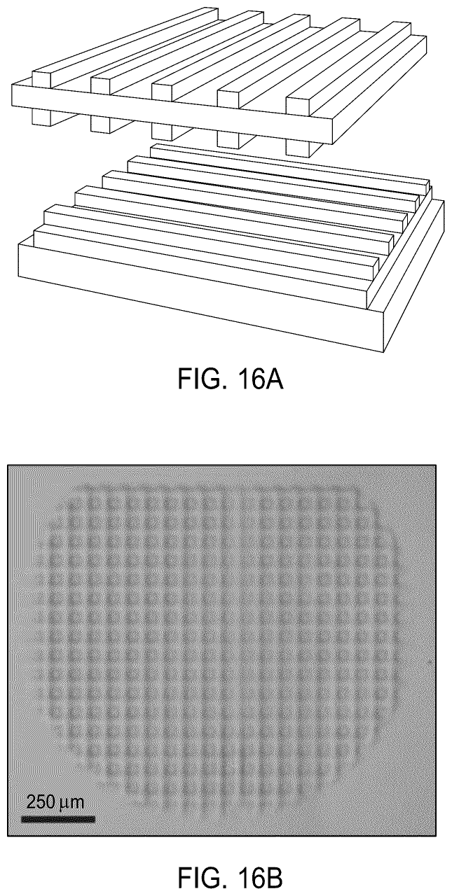

To form modules, strings of cells can be connected using the scheme in FIG. 15 (shown here is a 2-by-4 cm array suitable for testing). This 4T interconnection scheme provides independent series-interconnection of top and bottom cells and utilizes all the sub-cells with no end losses (unlike the 3T scheme). The interconnects (ICs) can be deposited and lithographically patterned directly on the Si handle using standard, high-volume semiconductor tools. The Si handles can be attached to high-thermal conductivity Direct Bond Copper (DBC) substrates, which are in turn soldered onto copper heat sinks. DBCs are a reliable platform because they have a similar coefficient of thermal expansion as Si. A key feature of the proposed modules is that all radiation-facing surfaces have very high IR reflectance (98%). This makes it possible to achieve a module-level efficiency that is within 95% of the cell efficiency while minimizing parasitic heating. In a scaled-up product consisting of many cell strings, two top strings would be connected in parallel with three bottom strings such that their outputs are voltage-matched.

A conventional wafer-bonder can be used to complete the bonding process. Preliminary testing has shown that this procedure can provide placement accuracy within acceptable tolerances (<3 μm). Note, however, that the use of a flip-chip bonder is not ideal for process scale-up and can lead to non-negligible sample-to-sample variability (˜30 μm tolerance). In the presence of lateral misalignment 10 μm, the 10 μm grid lines will not come into sufficient contact. In the presence of lateral misalignment exceeding 10 μm, the 10 μm wide grid lines on each surface will not come into sufficient contact for bonding, resulting in suspension failure.

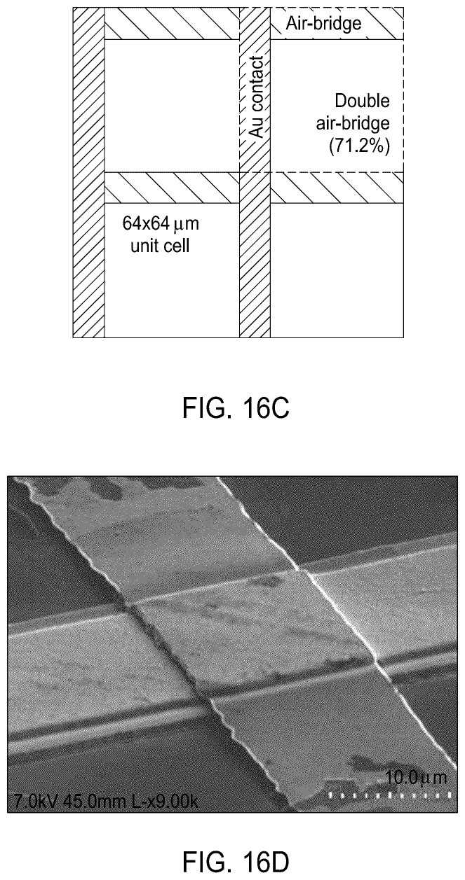

To mitigate the misalignment risk and enable process scale-up, an alternative design is developed where the grid lines on the top cell are rotated by 90° with respect to those on the bottom, allowing for the use of a conventional wafer bonder. As shown in FIG. 16A and FIG. 16D, vertically oriented Au-insulator-Au lines are deposited on the bottom cell, while horizontally oriented Au lines are deposited on the top cell. Au—Au bonding occurs at the intersections of these orthogonal gridlines. Preliminary testing shows that the resulting suspension exhibits excellent mechanical stability (FIG. 16B).

The perpendicular intermediate grid design can tolerate much larger misalignments (on the order of ˜50 μm) without impacting performance. Such tolerances can be achieved in a simple and high-throughput way by dicing the substrate (carrying the top cell) and Si handle (carrying the bottom cell) to specification and then aligning them along two edges. Although the perpendicular grid shades a portion of the bottom cell as in FIG. 16C (˜10-15%), those areas effectively function as ˜43%-efficient single-junction top ABCs that convert high energy photons into power and reflect/recycle ˜99% of the low energy photons back to the heat source. Thus, shadowing is expected to have a negligible impact on the total cell efficiency. In fact, in high temperature regimes where series resistance losses dominate, some shadowing can improve efficiency because it lowers the current density while preserving the incident spectrum.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. An optoelectronic device, comprising:
a substrate;
a bottom electrode disposed on the substrate;
a bottom photovoltaic cell disposed on the bottom electrode, wherein the bottom photovoltaic cell is comprised of multiple device layers forming a p-n junction;
a bottom bridge layer disposed on the bottom photovoltaic cell, wherein the bottom bridge layer is comprised of metal and includes a hole through which thermal radiation passes;
a top bridge layer disposed on the bottom bridge layer and bonded thereto, wherein the top bridge layer is comprised of metal and includes a hole through which thermal radiation passes;
a top photovoltaic cell disposed on the top bridge layer, such that the top bridge layer and the bottom bridge layer form a shared electrode between the top photovoltaic cell and the bottom photovoltaic cell, wherein the top photovoltaic cell is comprised of multiple device layers forming a p-n junction; and
a top electrode disposed on the top photovoltaic cell.

2. The optoelectronic device of claim 1 wherein the top bridge layer is bonded to the bottom bridge layer using cold weld bonding.

3. The optoelectronic device of claim 1 wherein the hole in the top bridge layer aligns with the hole in the bottom bridge layer and has a lattice structure formed therein.

4. The optoelectronic device of claim 1 wherein the top bridge layer and the bottom bridge layer are comprised of gold.

5. The optoelectronic device of claim 1 wherein the multiple device layers of at least one of the top photovoltaic cell and the bottom photovoltaic cell include a layer of indium gallium arsenide sandwiched between layers of indium phosphide.

6. The optoelectronic device of claim 1 wherein the multiple device layers of the top photovoltaic cell and the bottom photovoltaic cell are comprised of semiconductors selected from group III-V elements.

7. The optoelectronic device of claim 1 further comprises a terminal electrically coupled to the shared electrode formed by the top bridge layer and the bottom bridge layer.

8. The optoelectronic device of claim 1 further comprises a third photovoltaic cell interposed between the top photovoltaic cell and the top electrode, wherein the third thermophotovoltaic cell is comprised of multiple device layers forming a p-n junction.

9. An optoelectronic device, comprising:
a substrate;
a bottom electrode disposed on the substrate;
a bottom photovoltaic cell disposed on the bottom electrode, wherein the bottom photovoltaic cell is comprised of multiple device layers forming a p-n junction;
a shared bridge layer disposed on the bottom photovoltaic cell, wherein the shared bridge layer is comprised of metal and includes a hole through which thermal radiation passes;
a terminal electrically coupled to the shared bridge layer;
a top photovoltaic cell disposed on the shared bridge layer, such that the shared bridge layer is a shared electrode between the top photovoltaic cell and the bottom photovoltaic cell, wherein the top photovoltaic cell is comprised of multiple device layers forming a p-n junction; and
a top electrode disposed on the top photovoltaic cell.

10. The optoelectronic device of claim 9 wherein the shared bridge layer is comprised of gold.

11. The optoelectronic device of claim 9 wherein the multiple device layers of at least one of the top photovoltaic cell and the bottom photovoltaic cell include a layer of indium gallium arsenide sandwiched between layers of indium phosphide.

12. The optoelectronic device of claim 9 wherein the multiple device layers of the top photovoltaic cell and the bottom photovoltaic cell are comprised of semiconductors selected from group III-V elements.

13. An optoelectronic device, comprising:
a substrate;
a bottom electrode disposed on the substrate;
a bottom photovoltaic cell disposed on the bottom electrode, wherein the bottom thermophotovoltaic cell is comprised of multiple device layers forming a p-n junction;
a bottom bridge layer disposed on the bottom photovoltaic cell, wherein the bottom bridge layer is comprised of metal and includes a hole through which thermal radiation passes;
a bottom terminal electrically coupled to the bottom bridge layer;
an insulator layer disposed on the bottom bridge layer;
a top bridge layer disposed on the insulator layer, wherein the top bridge layer is comprised of metal and includes a hole through which thermal radiation passes;
a top terminal electrically coupled to the top bridge layer and configured to output current from the top photovoltaic cell;
a top photovoltaic cell disposed on the top bridge layer, such that the top bridge layer and the bottom bridge layer form a shared electrode between the top photovoltaic cell and the bottom photovoltaic cell, wherein the top thermophotovoltaic cell is comprised of multiple device layers forming a p-n junction; and
a top electrode disposed on the top photovoltaic cell.

14. The optoelectronic device of claim 1 wherein the hole in the top bridge layer aligns with the hole in the bottom bridge layer and has a lattice structure formed therein.

15. The optoelectronic device of claim 1 wherein the top bridge layer and the bottom bridge layer are comprised of gold.

16. The optoelectronic device of claim 1 wherein the multiple device layers of at least one of the top photovoltaic cell and the bottom photovoltaic cell include a layer of indium gallium arsenide sandwiched between layers of indium phosphide.

17. The optoelectronic device of claim 1 wherein the multiple device layers of the top photovoltaic cell and the bottom photovoltaic cell are comprised of semiconductors selected from group III-V elements.
